(19) United States
(12) Patent Application Publication
(10) Pub. No.: US 2024/0426952 A1
(43) Pub. Date: Dec. 26, 2024

(54) MAGNETIC RESONANCE SURFACE COIL WITH HEAT DISSIPATION ELEMENT

(71) Applicant: Siemens Healthineers AG, Forchheim (DE)

(72) Inventors: Stephan Zink, Nürnberg (DE); Vincent Kelber, Bamberg (DE)

(21) Appl. No.: 18/740,875

(22) Filed: Jun. 12, 2024

(30) Foreign Application Priority Data
Jun. 21, 2023 (DE) 10 2023 205 791.3

(51) Int. Cl. G01R 33/34; G01R 33/341

(52) U.S. Cl. CPC G01R 33/3403; G01R 33/341

(57) ABSTRACT

A magnetic resonance (MR) surface coil with heat dissipation element, a system including an MR surface coil and a patient table, and a magnetic resonance apparatus are described herein. The MR surface coil includes at least one RF antenna for transmitting and/or receiving RF signals, at least one electronic component electronically connected to the at least one RF antenna, a cover within which the at least one RF antenna and the at least one electronic component are arranged, and at least one heat dissipation element thermally connected to the at least one electronic component. The at least heat dissipation element is configured to dissipate thermal energy from the at least one electronic component to the outside and/or to distribute the thermal energy over a wide area.

The present patent document claims the benefit of German Patent Application No. 10 2023 205 791.3, filed Jun. 21, 2023, which is hereby incorporated by reference in its entirety

### TECHNICAL FIELD

The disclosure relates to an MR surface coil with heat dissipation element, a system including an MR surface coil and a patient table, and a magnetic resonance apparatus.

### BACKGROUND

In medical engineering, imaging using magnetic resonance (MR), also known as magnetic resonance tomography (MRT) or magnetic resonance imaging (MRI), is characterized by high soft tissue contrast. Herein, an object to be examined, (e.g., a human or animal patient), is positioned in an examination area of a magnetic resonance apparatus with a static main magnetic field. During a magnetic resonance scan, radiation-frequency (RF) pulses and gradient pulses are radiated into the examination area to excite the slices to be scanned. This triggers spatially encoded magnetic resonance signals in the object to be examined. The magnetic resonance signals may be received as scan data from surface coils and used to reconstruct magnetic resonance maps.

The surface coils may be attached locally directly to the object to be examined and therefore they may also be called local coils. Due to the proximity of the surface coil to the location where the magnetic resonance signal is generated, the scan data received by a surface coil advantageously has a high signal-to-noise ratio. It is also possible for surface coils to be used to transmit RF signals. Surface coils may have one or more RF antennas, also called coil elements, to transmit and/or receive the RF signals.

Surface coils may heat up during the performance of a magnetic resonance scan. Since the surface coils may be in direct contact with the patient, it is necessary to limit the amount they heat up.

### SUMMARY AND DESCRIPTION

It is the object of the present disclosure to reduce the risk to patients from excessive heating of the surface coils. In particular, temperature peaks in the areas where such components heat up should be avoided.

The scope of the present disclosure is defined solely by the appended claims and is not affected to any degree by the statements within this summary. The present embodiments may obviate one or more of the drawbacks or limitations in the related art.

Accordingly, an MR surface coil is proposed that includes at least one RF antenna for transmitting and/or receiving RF signals and at least one electronic component, which is electrically connected to the at least one RF antenna. The at least one RF antenna and the at least one electronic component are arranged within a cover of the MR surface coil. The cover may delimit the MR surface coil toward the outside.

Furthermore, the MR surface coil includes at least one heat dissipation element which is thermally connected to the at least one electronic component. Herein, the at least heat dissipation element is configured to dissipate thermal energy from the at least one electronic component to the outside and/or to distribute the thermal energy over a wide area.

The dissipation and/or distribution of the thermal energy advantageously enables the heat acting on the patient to be reduced. Furthermore, it is advantageously possible for temperature peaks to be avoided, in particular in areas in which the at least one electronic component is located. The thermal energy may be thermal energy generated by the at least one electronic component.

The thermal energy may be generated by induction of an RF signal during a scan. Furthermore, an MR surface coil may also be supplied with current, in particular direct current, outside a scan, which may cause the at least one electronic component to heat up. In the case of components whose electrical resistance increases as the temperature rises, it is even conceivable that more electrical power has to be applied at higher temperatures and this in turn causes an additional increase in temperature.

Advantageously, the at least one heat dissipation element causes the locally generated heat to be distributed over as wide an area as possible on the surface of the MR surface coil and/or deflected in a targeted manner, thus avoiding strong local heating. Advantageously, more power may be introduced into the MR surface coil by the at least heat dissipation element. As a result, higher pulses may be permitted and this may advantageously increase the image quality of the magnetic resonance maps. Furthermore, the geometry of the electronic components may be reduced because there is no need for any spacer materials to limit heating.

The at least one RF antenna may include an electrical conductor loop. It is possible for an (electromagnetic) RF signal to be induced into the RF antenna. The at least one electronic component may include electrical capacitors, inductors, resistors, diodes, etc. The at least one electronic component may include a preamplifier for amplifying a received RF signal.

The at least one electronic component and the at least one RF antenna may be connected to one another by an electric line, for example, an electrically conductive wire. Furthermore, the at least one electronic component may also be electrically connected to any plug-in connection of the MR surface coil with which the MR surface coil may be connected to a magnetic resonance apparatus. However, in addition to wired MR surface coils, wireless MR surface coils are also conceivable.

The dissipation of the thermal energy to the outside may cause the thermal energy to be transported away from the MR surface coil. Advantageously, this limits a possible rise in temperature on the surface of the MR surface coil.

The distribution of the thermal energy over a wide area may reduce a local concentration of the thermal energy. This advantageously enables hotspots to be avoided or reduced. The wide-area distribution of the thermal energy may take place on a surface parallel to the surface of the MR surface coil.

The at least one heat dissipation element is advantageously thermally connected or coupled to the at least one electronic component such that the thermal energy may be transported particularly quickly away from the at least one electronic component to the heat dissipation element. The heat dissipation element may be in direct contact with the at least one electronic component or only separated therefrom by a thermally negligible intermediate layer. Herein, the intermediate layer may be thermally negligible if the layer is sufficiently thin and/or if the layer has high thermal conductivity, for example, more than 2 W/(m·K).

The MR surface coil may be flat, e.g., two-dimensional. In particular, the MR surface coil has exactly two opposing surfaces, which form a large part of the entire surface of the MR surface coil and are referred to as main surfaces in the following. In particular, the proportion of the two main surfaces in the entire surface of the MR surface coil is at least 80 percent or at least 90 percent. In particular, the two main surfaces are arranged parallel to one another.

In particular, the at least one electronic component includes a plurality of electronic components. In particular, the plurality of electronic components are distributed over a surface. In particular, this surface is arranged parallel to the two main surfaces.

The MR surface coil may be flexible. In certain examples, the shape of the MR surface coil may be changed. Advantageously, the MR surface coil may be configured to the shape of the object to be examined. In certain examples, the MR surface coil may be stretchable and/or elastic and/or pliable. The MR surface coil may be configured in the shape of a blanket. Advantageously, the MR surface coil may be placed over the object to be examined like a blanket.

In certain examples, the at least one heat dissipation element may include at least one distribution layer, (e.g., a thermal distribution layer), which is arranged between the at least one electronic component and the cover and is configured to distribute at least part of the thermal energy on a surface of the MR surface coil. Advantageously, this reduces or avoids thermal hotspots.

In certain examples, the at least one distribution layer may be flat, e.g., two-dimensional. In particular, the distribution layer has a surface A and an edge delimiting the surface with a length L, wherein L²/A>20, L²/A>50, or L²/A>100.

In certain examples, the at least one distribution layer, in particular its surface A, is arranged parallel to the two main surfaces. Advantageously, this causes the thermal energy to be distributed on at least one of the two main surfaces.

In certain examples, the at least one distribution layer includes a fire-resistant fleece, a thermal fleece, a heat-resistant film, a coated textile, a foam material, or combinations thereof. Advantageously, these materials are particularly suitable for distributing the thermal energy. In certain examples, the at least one distribution layer has low thermal conductivity, for example, less than 5 W/(m·K), less than 2 W/(m·K), or less than 1 W/(m·K). In certain examples, the at least one distribution layer inhibits heat propagation toward the surface, in particular the main surface, of the MR surface coil. In certain examples, the thermal energy is instead distributed more strongly in the lateral direction, i.e., parallel to the surface, in particular the main surface, of the MR surface coil.

Advantageously, the at least one distribution layer may be introduced very flexibly. In particular, the geometry thereof may be easily adapted. In certain examples, thicker distribution layers are used at higher temperatures. The use of distribution layers on a wide variety of coil shapes is conceivable, since the shape of the distribution layers may advantageously be adapted as required.

Advantageously, a very light material may be used for the at least one distribution layer. In addition, this is advantageously a cost-effective implementation of a heat dissipation element. There may not be a need for design changes if the at least one distribution layer is introduced subsequently. Advantageously, the at least one distribution layer also provides (possibly additional) padding for the at least one electronic component.

In certain examples, the at least one distribution layer is embodied as flexible. In particular, the at least one distribution layer includes a flexible material. This advantageously enables negative influences, such as stiffening of the MR surface coil, to be avoided, so that the flexibility of the entire MR surface coil remains provided.

In certain examples, the heat dissipation element includes at least one heat conductor, in particular a filament, which is arranged at least partially within the cover and is embodied to conduct at least part of the heat along the heat conductor out of the MR surface coil.

For example, the at least one heat conductor may be combined with the at least one distribution layer. In particular, the at least one heat conductor is connected, in particular thermally connected, to the at least one distribution layer, in particular brought into direct contact therewith.

For example, the at least one heat conductor may have a meandering structure, in particular in sections. In particular, the at least one heat conductor may have a meandering structure in the vicinity of the at least one electronic component.

In certain examples, the at least one heat dissipation element includes at least one replaceable cooling pack. Advantageously, the cooling pack is embodied to absorb thermal energy. Advantageously, the at least one cooling pack may reduce the thermal energy in a targeted manner at the location of the at least one electronic component.

Advantageously, the cooling pack may be repeatedly introduced into the MR surface coil in a cool state and removed again in a heated state. For example, the cooling pack in the heated state may be replaced by another cooling pack that is in a cool state. Advantageously, this enables heat dissipation to be provided at all times.

The MR surface coil may have at least one reclosable opening through which the at least one cooling pack may be introduced into the MR surface coil. This at least one reclosable opening may have a zipper and/or a hook and loop fastener.

In certain examples, the at least one heat dissipation element includes at least one fastening element arranged outside the cover for fastening the MR surface coil to the patient and/or to the patient table, wherein the at least one fastening element is embodied to absorb at least part of the thermal energy.

The fastening element may be a strap. In certain examples, the strap has particularly high thermal conductivity in the area of the at least one electronic component. Straps may already be present and may be used flexibly. In certain examples, straps are already plugged into defined positions, which may enable temperature control.

In certain examples, the at least one heat dissipation element includes at least one heat transfer element, which is arranged between the at least one electronic component and the cover and is embodied to transfer at least part of the thermal energy to at least one counterpart arranged outside the MR surface coil.

In certain examples, the at least one heat transfer element has particularly high thermal conductivity. The at least one heat transfer element may include a material with a thermal conductivity λ of at least 10 W/(m·K), at least 30 W/(m·K), or at least 100 W/(m·K). The material of the at least one heat transfer element may include aluminum or copper.

In certain examples, the MR surface coil includes at least one first positioning unit in order to position the at least one heat transfer element as precisely as possible relative to the at least one counterpart arranged outside the MR surface coil. The at least one first positioning unit may include an optical marking and/or a mechanical guide.

Furthermore, a system is proposed that includes at least one MR surface coil as described above and a patient table, wherein the patient table has the at least one counterpart that is suitable for absorbing at least part of the thermal energy from the at least one heat transfer element.

Advantageously, this enables particularly effective heat dissipation to be provided so that it is also possible to use electronic components with high heat generation.

Furthermore, a system is proposed that includes at least one MR surface coil MR-surface coil as described above and a patient table, wherein the patient table has at least one heat dissipation element, wherein the at least one heat dissipation element is embodied to absorb at least part of the thermal energy when the MR surface coil is arranged on the patient table.

The patient table may be suitable for supporting the object to be examined during a magnetic resonance examination, in particular a magnetic resonance scan.

In certain examples, the patient table includes at least one second positioning unit in order to position the at least one MR surface coil as precisely as possible relative to the patient table. The at least one second positioning unit may include an optical marking and/or a mechanical guide. In particular, the at least one first positioning unit of the MR surface coil may interact with the at least one first positioning unit of the patient table.

For example, optical markings of the at least one first positioning unit of the MR surface coil and the at least one second positioning unit of the patient table may be arranged such that correct relative positioning is provided when the markings overlap. For example, the at least one first positioning unit of the MR surface coil may snap into the at least one second positioning unit of the patient table.

Furthermore, a magnetic resonance apparatus with at least one MR surface coil as described above and/or a system as described above is proposed.

### BRIEF DESCRIPTION OF THE DRAWINGS

Further advantages, features, and details of the disclosure emerge from the embodiments described below and from the drawings. Corresponding parts are provided with the same reference symbols in all figures, in which:

FIG. 1 depicts an example of a magnetic resonance apparatus with a patient table and an MR surface coil.

FIGS. 2 and 3 depict examples of an MR surface coil with a plurality of distribution layers as heat dissipation elements.

FIG. 4 depicts an example of an MR surface coil with a plurality of heat conductors as heat dissipation elements.

FIG. 5 depicts an example of an MR surface coil with a plurality of cooling packs as heat dissipation elements.

FIG. 6 depicts an example of a system including an MR surface coil and a patient table.

### DETAILED DESCRIPTION

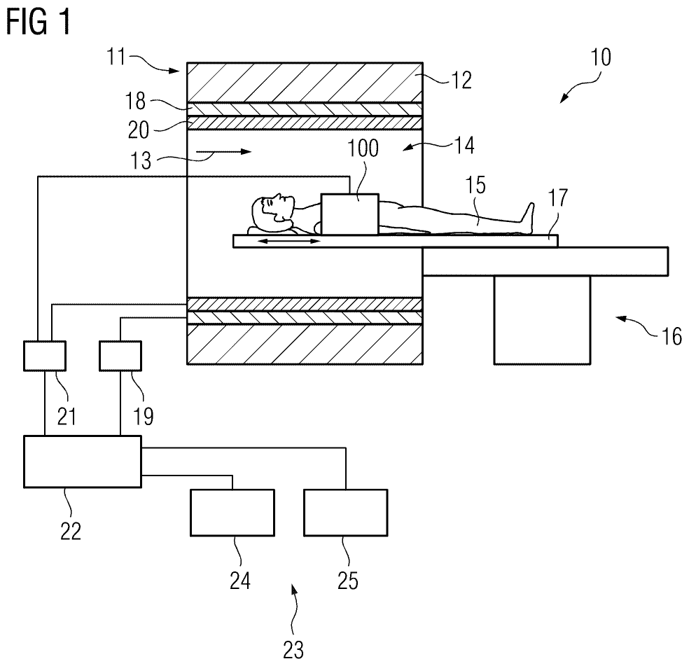

FIG. 1 is a schematic representation of a magnetic resonance apparatus 10. The magnetic resonance apparatus 10 includes a magnet unit 11, which has a main magnet 12 for generating a strong and in particular temporally constant main magnetic field 13. In addition, the magnetic resonance apparatus 10 includes a patient receiving area 14 for receiving a patient 15. In the present embodiment, the patient receiving area 14 is cylindrical in shape and is surrounded by the magnet unit 11 in a cylindrical shape in a circumferential direction. However, a different embodiment of the patient receiving area 14 is also conceivable. The patient 15 may be pushed into the patient receiving area 14 by a patient support apparatus 16 of the magnetic resonance apparatus 10. For this purpose, the patient support apparatus 16 has a patient table 17 configured to be movable within the patient receiving area 14 for supporting the patient 15.

The magnet unit 11 furthermore has a gradient coil unit 18 for generating magnetic field gradients that are used for spatial encoding during imaging. The gradient coil unit 18 is controlled by a gradient control unit 19 of the magnetic resonance apparatus 10. The magnet unit 11 furthermore includes a radio-frequency antenna unit 20, which, in the present embodiment, is embodied as a body coil permanently integrated into the magnetic resonance apparatus 10. The radio-frequency antenna unit 20 is controlled by a radio-frequency antenna control unit 21 of the magnetic resonance apparatus 10 and radiates radio-frequency magnetic resonance sequences into an examination area, which is substantially formed by a patient receiving area 14 of the magnetic resonance apparatus 10. This causes the main magnetic field 13 generated by the main magnet 12 to excite atomic nuclei. Relaxation of the excited atomic nuclei causes magnetic resonance signals to be generated. The radio-frequency antenna unit 20 is also embodied to receive the magnetic resonance signals.

The magnetic resonance apparatus 10 has a system control unit 22 for controlling the main magnet 12, the gradient control unit 19 and for controlling the radio-frequency antenna control unit 21. The system control unit 22 controls the magnetic resonance apparatus 10 centrally, such as the performance of a predetermined imaging gradient echo sequence. In addition, the system control unit 22 includes an evaluation unit, not shown in any more detail, for evaluating the magnetic resonance signals captured during the magnetic resonance examination. Furthermore, the magnetic resonance apparatus 10 includes a user interface 23 connected to the system control unit 22. Control information, such as imaging parameters and reconstructed magnetic resonance maps, may be displayed on a display unit 24, for example, on at least one monitor, of the user interface 23 for medical operating personnel. Furthermore, the user interface 23 has an input unit 25 by which information and/or parameters may be input by the medical operating personnel during a scanning procedure.

The magnetic resonance apparatus further includes an MR surface coil 100, which is configured to transmit RF signals, in particular excitation pulses, and/or to receive RF signals, in particular magnetic resonance signals. The MR surface coil 100 is arranged directly on the body of the patient 15, here on the upper body. In certain examples, the MR surface coil 100 is embodied as flexible so that it may be easily configured to the shape of the patient 15. Due to the proximity of the location where the magnetic resonance signals are generated, the magnetic resonance signals received by the MR surface coil 100 advantageously have a particularly high signal-to-noise ratio.

The MR surface coil 100 in particular includes at least one RF antenna for transmitting and/or receiving RF signals, at least one heat-generating electronic component electrically connected to the at least one RF antenna, a cover within which the at least one RF antenna and the at least one electronic component are arranged, and at least one heat dissipation element thermally connected to the at least one electronic component, wherein the at least heat dissipation element is configured to dissipate thermal energy from the at least one electronic component to the outside and/or to distribute the thermal energy over a wide area.

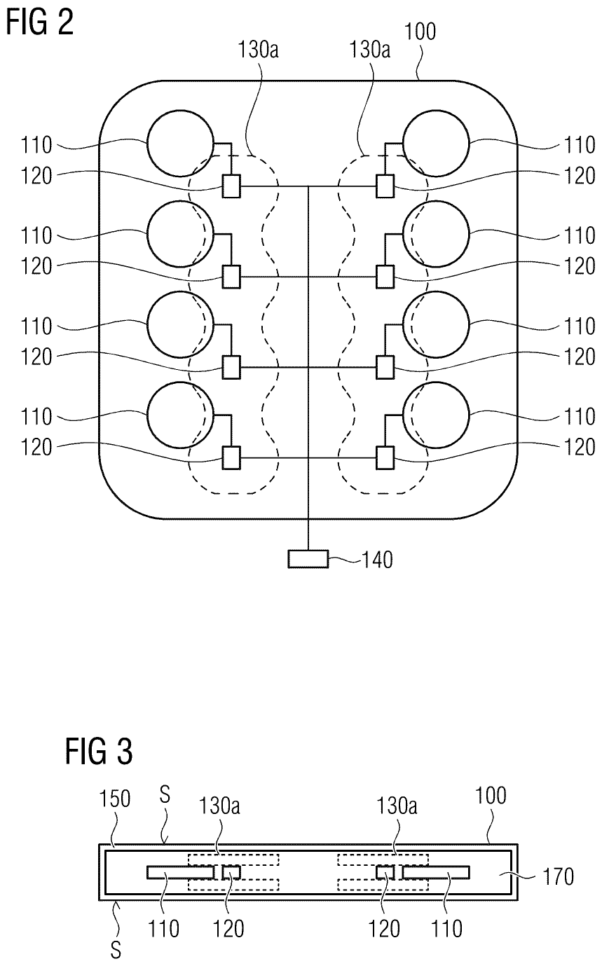

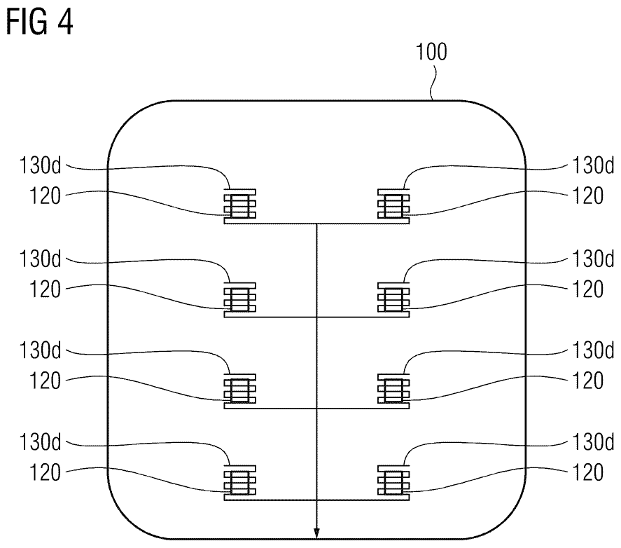

FIG. 2 shows a possible embodiment of the MR surface coil 100 in a plan view. The MR surface coil 100 includes a plurality of RF antennas 110 for transmitting and/or receiving RF signals. (The RF antennas 110 are not depicted in FIGS. 4-6 for the sake of clarity.) The RF antennas 110 are electrically connected to a plurality of electronic components 120. In the example shown, each RF antenna 110 is in each case connected to one electronic component 120. However, it is also conceivable for the MR surface coil 100 to have more or fewer electronic components 120 per RF antenna 110. Electronic components 120 may provide that the magnetic resonance signals received by the RF antennas 110 are amplified and/or that the resonant frequency of the MR surface coil 100 is detuned when RF signals are transmitted by the radio-frequency antenna unit 20.

The electronic components are in turn electrically connected to a plug-in connection 140 with which the MR surface coil 100 may be connected to the magnetic resonance apparatus.

The MR surface coil 100 includes distribution layers 103a as heat dissipation elements. As may be seen in FIG. 3, the distribution layers 130a are arranged between the electronic components 120 and the cover 150. These provide that at least part of the thermal energy is distributed on a surface, in particular a main surface S, of the MR surface coil 100.

In the example shown here, the distribution layers 130a are arranged on both sides between the centrally arranged electronic components 120 and the outer cover 150. However, it is also conceivable for the distribution layers 130a to be arranged on only one side between the electronic components 120 and the cover 150. This side may be the side facing away from the patient 15.

The RF antennas 110, the electronic components 120, and the distribution layers 130a may be embedded in a foam structure 170.

The introduction of the distribution layers 103a enables temperature peaks that occur in the area of the electronic components 120 to be avoided. The temperature is distributed over the surface by the distribution layers 130a, deflected in a target manner, and/or removed. The edge surface may be as large as possible in order to provide the largest possible area for convection. In certain examples, the distribution layers 103a in each case have a surface with a surface area A and an edge delimiting the surface edge with a length L, wherein L²/A>20, L²/A>50, or L²/A>100.

Herein, the distribution layers 103a may include different materials such as fire-resistant fleeces, foams, thermal fleeces, heat-resistant films, coated textiles, or combinations thereof.

FIG. 4 shows a possible embodiment of the MR surface coil 100 according to which the surface coil 100 includes heat conductors 130d arranged within the cover as heat dissipation elements. The heat conductors 130d are embodied as temperature filaments that lead out of the MR surface coil 100 and transfer the temperature in a targeted manner.

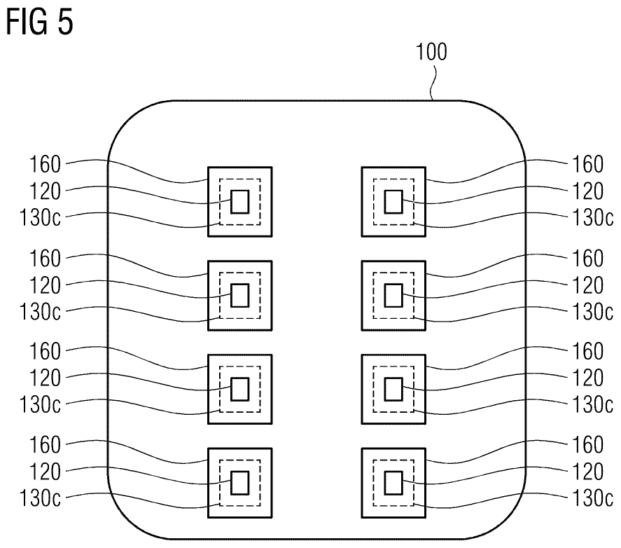

FIG. 5 shows by way of example an MR surface coil 100 with insertable or replaceable cooling packs 130c as heat dissipation elements. The cooling packs 130c may be arranged at the temperature hotspots of the MR surface coil 100, in particular at the heat-generating electronic components 120. The cooling packs 130c may be inserted and removed again via an opening 160.

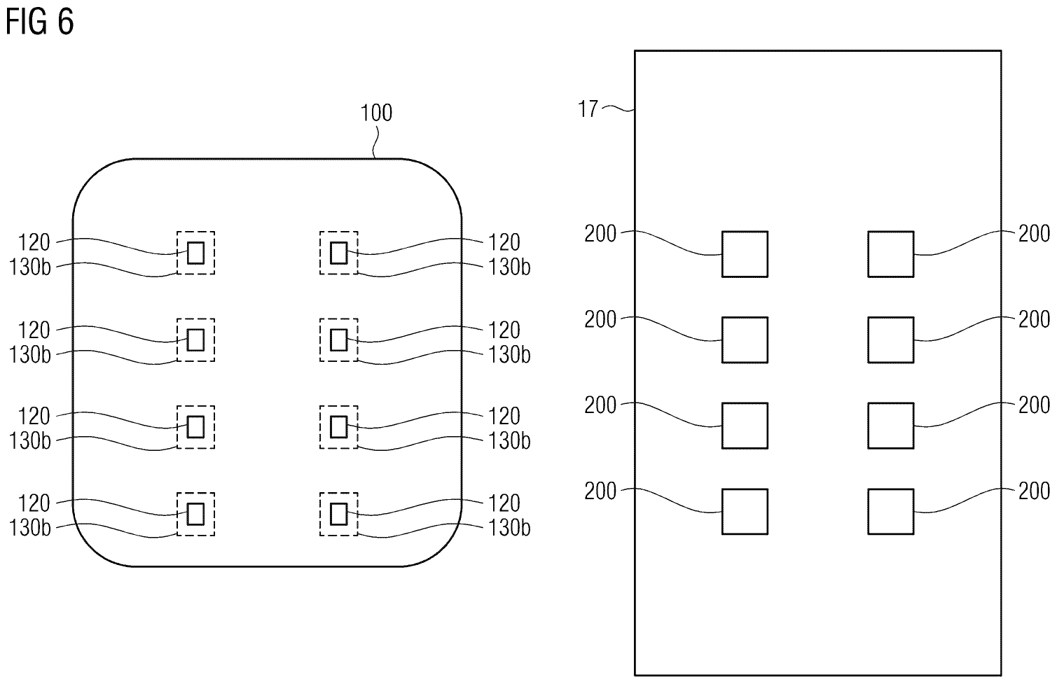

FIG. 6 shows a further possibility for removing the heat. Here, the MR surface coil 100 has heat transfer elements 130b, in particular heat transfer pads, as heat dissipation elements. The heat transfer elements 130b may be coupled to counterparts 200 arranged outside the MR surface coil 100 on the patient table 17. Via these contact points and/or coupling points, which in particular have strong thermal conductivity, the heat is transferred out of the MR surface coil 100 in a targeted manner into patient table 15 and dissipated. In certain examples, the heat transfer elements 130b have a material with a thermal conductivity λ of at least 2 W/(m·K), at least 4 W/(m·K), or at least 10 W/(m·K).

Furthermore, it would be possible to use fastening materials that may already be present on the MR surface coil 100, in particular straps, for targeted temperature control. In certain examples, thermally conductive materials and/or shields may be used for this purpose.

Finally, reference is made once again to the fact that the MR surface coils described in detail above and the magnetic resonance apparatus are only embodiments which may be modified by the person skilled in the art in a wide variety of ways without departing from the scope of the disclosure. Furthermore, the use of the indefinite articles “a” or “an” does not exclude the possibility that the features in question may also be present on a multiple basis. Likewise, the term “unit” does not preclude the possibility of the components in question including a plurality of interacting subcomponents that may also be spatially distributed.

It is to be understood that the elements and features recited in the appended claims may be combined in different ways to produce new claims that likewise fall within the scope of the present disclosure. Thus, whereas the dependent claims appended below depend on only a single independent or dependent claim, it is to be understood that these dependent claims may, alternatively, be made to depend in the alternative from any preceding or following claim, whether independent or dependent, and that such new combinations are to be understood as forming a part of the present specification.

While the present disclosure has been described above by reference to various embodiments, it may be understood that changes and modifications may be made to the described embodiments. It is therefore intended that the foregoing description be regarded as illustrative rather than limiting, and that it be understood that all equivalents and/or combinations of embodiments are intended to be included in this description.

1. A magnetic resonance (MR) surface coil comprising:
at least one radio frequency (RF) antenna for transmitting and/or receiving RF signals;
at least one electronic component electrically connected to the at least one RF antenna;
a cover within which the at least one RF antenna and the at least one electronic component are arranged; and
at least one heat dissipation element thermally connected to the at least one electronic component,
wherein the at least one heat dissipation element is configured to dissipate thermal energy from the at least one electronic component outside and/or to distribute the thermal energy over an area.

2. The MR surface coil of claim 1, wherein the MR surface coil is flexible.

3. The MR surface coil of claim 1, wherein the at least one heat dissipation element comprises at least one distribution layer arranged between the at least one electronic component and the cover, and
wherein the at least one distribution layer is configured to distribute at least part of the thermal energy on a surface of the surface coil.

4. The MR surface coil of claim 3, wherein the at least one distribution layer has a surface with a surface area A and an edge delimiting the surface with an edge length L, and
wherein L²/A>20.

5. The MR surface coil of claim 3, wherein the at least one distribution layer has a thermal conductivity λ of less than 5 W/(m·K).

6. The MR surface coil of claim 3, wherein the at least one distribution layer comprises a fire-resistant fleece, a thermal fleece, a heat-resistant film, a coated textile, a foam material, or a combination thereof.

7. The MR surface coil of claim 3, wherein the at least one distribution layer comprises a flexible material.

8. The MR surface coil of claim 1, wherein the at least one heat dissipation element comprises at least one heat conductor arranged at least partially within the cover, and
wherein the at least one heat dissipation element is configured to conduct at least part of a heat along the at least one heat conductor out of the MR surface coil.

9. The MR surface coil of claim 8, wherein the at least one heat conductor comprises a filament.

10. The MR surface coil of claim 1, wherein the at least one heat dissipation element comprises at least one replaceable cooling pack.

11. The MR surface coil of claim 1, wherein the at least one heat dissipation element comprises at least one fastening element arranged outside the cover,
wherein the at least one fastening element is configured to fasten the MR surface coil to a patient and/or to a patient table, and
wherein the at least one fastening element is configured to absorb at least part of the thermal energy.

12. The MR surface coil of claim 11, wherein the at least one fastening element comprises at least one strap.

13. The MR surface coil of claim 1, wherein the at least one heat dissipation element comprises at least one heat transfer element arranged between the at least one electronic component and the cover, and
wherein the at least one heat transfer element is configured to transfer at least part of the thermal energy to at least one counterpart arranged outside the MR surface coil.

14. The MR surface coil of claim 13, wherein the at least one heat transfer element comprises a material with a thermal conductivity λ of at least 10 W/(m·K).

15. A system comprising:
a patient table; and
a magnetic resonance (MR) surface coil having:
at least one radio frequency (RF) antenna for transmitting and/or receiving RF signals;
at least one electronic component electrically connected to the at least one RF antenna;
a cover within which the at least one RF antenna and the at least one electronic component are arranged; and
at least one heat dissipation element thermally connected to the at least one electronic component,
wherein the at least one heat dissipation element is configured to dissipate thermal energy from the at least one electronic component outside and/or to distribute the thermal energy over an area.

16. The system of claim 15, wherein the at least one heat dissipation element comprises at least one heat transfer element arranged between the at least one electronic component and the cover,
wherein the at least one heat transfer element is configured to transfer at least part of the thermal energy to at least one counterpart arranged outside the MR surface coil, and
wherein the patient table has the at least one counterpart configured to absorb the at least part of the thermal energy from the at least one heat transfer element.

17. The system of claim 15, wherein the patient table has the at least one heat dissipation element, and
wherein the at least one heat dissipation element is configured to absorb at least part of the thermal energy when the MR surface coil is arranged on the patient table.

18. A magnetic resonance apparatus comprising:
a magnetic resonance (MR) surface coil having:
at least one radio frequency (RF) antenna for transmitting and/or receiving RF signals;
at least one electronic component electrically connected to the at least one RF antenna;
a cover within which the at least one RF antenna and the at least one electronic component are arranged; and
at least one heat dissipation element thermally connected to the at least one electronic component,
wherein the at least one heat dissipation element is configured to dissipate thermal energy from the at least one electronic component outside and/or to distribute the thermal energy over an area.
